(19) United States
(12) Patent Application Publication
(10) Pub. No.: US 2024/0188322 A1
(43) Pub. Date: Jun. 6, 2024

(54) DISPLAY PANEL INCLUDING PIXEL DRIVING TRANSISTOR

(71) Applicant: SAMSUNG DISPLAY CO., LTD., Yongin-si (KR)

(72) Inventors: Sangwoo Sohn, Yongin-si (KR); Eunhye Ko, Yongin-si (KR); Yeon Keon Moon, Yongin-si (KR); Sunhee Lee, Yongin-si (KR); Hyunmo Lee, Yongin-si (KR); Hyunjun Jeong, Yongin-si (KR)

(21) Appl. No.: 18/462,389

(22) Filed: Sep. 6, 2023

(30) Foreign Application Priority Data
Dec. 1, 2022 (KR) 10-2022-0166096

(51) Int. Cl. H10K 50/30; H10K 59/121; H10K 59/80; H10K 71/00; H10K 77/10

(52) U.S. Cl. CPC H10K 50/30; H10K 59/1213; H10K 59/805; H10K 71/621; H10K 77/10; H10K 2102/302

(57) ABSTRACT

A display panel includes a light emitting element and a pixel circuit electrically connected to the light emitting element and includes a first transistor and a second transistor. The first transistor includes a first semiconductor pattern including a first source region, a first drain region, and a first channel region, a first gate electrode disposed over the first channel region, and a first conductive pattern disposed under the first channel region. The second transistor includes a second semiconductor pattern including a second source region, a second drain region, and a second channel region, a second gate electrode disposed over the second channel region, and a second conductive pattern disposed under the second channel region. A length of the first conductive pattern is longer than a length of the first gate electrode. The second conductive pattern is shorter than a length of the second gate electrode.

### CROSS-REFERENCE TO RELATED APPLICATIONS

This application claims priority under 35 U.S.C. § 119 to Korean Patent Application No. 10-2022-0166096 filed on Dec. 1, 2022, in the Korean Intellectual Property Office, the disclosure of which is incorporated by reference herein in its entirety.

### TECHNICAL FIELD

The present disclosure relates to a display panel and, more specifically, to a display panel including a transistor driving a pixel.

### DISCUSSION OF THE RELATED ART

Display devices, such as those used in televisions, mobile phones, tablet computers, vehicle navigation units, game consoles, and the like, may include a display panel that provides an image to a user through a display screen. The display panel may include a light emitting element that generates light and a pixel circuit that controls the amount of current flowing to the light emitting element. The pixel circuit may include organically connected transistors, and the transistors may affect the drive reliability of the display panel.

### SUMMARY

A display panel includes a light emitting element and a pixel circuit that is electrically connected to the light emitting element and that includes a first transistor and a second transistor. The first transistor includes a first semiconductor pattern including a first source region, a first drain region, and a first channel region disposed between the first source region and the first drain region, a first gate electrode disposed over the first channel region, and a first conductive pattern disposed under the first channel region. The second transistor includes a second semiconductor pattern including a second source region, a second drain region, and a second channel region disposed between the second source region and the second drain region, a second gate electrode disposed over the second channel region, and a second conductive pattern disposed under the second channel region. The first conductive pattern overlaps the first gate electrode. A length of the first conductive pattern is longer than a length of the first gate electrode. The second conductive pattern overlaps the second gate electrode. A length of the second conductive pattern is shorter than a length of the second gate electrode.

Each of the first semiconductor pattern and the second semiconductor pattern may include a metal oxide semiconductor material.

The first semiconductor pattern and the second semiconductor pattern may be disposed on a same layer.

The first conductive pattern and the second conductive pattern may include a same material.

The first conductive pattern and the second conductive pattern may be disposed on a same layer.

The length of the second conductive pattern may be shorter than the length of the first conductive pattern.

The second conductive pattern may include a plurality of patterns that overlap the second channel region and that are spaced apart from each other.

The second channel region may have a stepped shape corresponding to an outer end of the second conductive pattern.

The second gate electrode may have a stepped shape corresponding to the stepped shape of the second channel region.

The second conductive pattern may be electrically connected to the second gate electrode.

The second conductive pattern may be a floating electrode.

The light emitting element may include a first electrode, a second electrode, and an emissive layer disposed between the first electrode and the second electrode, and the first electrode may be electrically connected to the first source region.

The first source region may be electrically connected to the first gate electrode.

The display panel may further include a buffer layer disposed between the first conductive pattern and the first channel region, a first insulating layer disposed between the first channel region and the first gate electrode, and a second insulating layer disposed on the first gate electrode. At least one of the buffer layer, the first insulating layer, and the second insulating layer may include an inorganic layer.

The buffer layer may be thicker than the first insulating layer.

The first insulating layer may include an insulating pattern that overlaps the first channel region without overlapping the first source region and the first drain region.

A display panel includes a light emitting element and a pixel circuit that is electrically connected to the light emitting element and that includes a drive transistor and a switching transistor. The drive transistor includes a first semiconductor pattern including a first channel region, a first source region, and a first drain region, a first gate electrode disposed over the first channel region and electrically connected to the first source region, and a first conductive pattern disposed under the first channel region. The switching transistor includes a second semiconductor pattern including a second channel region, a second source region, and a second drain region, a second gate electrode disposed over the second channel region, and a second conductive pattern disposed under the second channel region. The second conductive pattern overlaps the second gate electrode. A length of the second conductive pattern is shorter than a length of the second gate electrode.

In a plan view, an outer end of the first conductive pattern may be spaced apart from the first channel region, and an outer end of the second conductive pattern may overlap the second channel region.

Each of the second channel region and the second gate electrode may have a stepped shape.

The second conductive pattern may include a plurality of patterns spaced apart from each other in a region corresponding to the second channel region.

### BRIEF DESCRIPTION OF THE FIGURES

The above and other objects and features of the present disclosure will become apparent by describing in detail embodiments thereof with reference to the accompanying drawings.

FIG. 1 is a block diagram of a display device according to an embodiment of the present disclosure.

FIG. 2 is an equivalent circuit diagram of a pixel according to an embodiment of the present disclosure.

FIGS. 3A to 3C are cross-sectional views of a display panel according to an embodiment of the present disclosure.

FIG. 4A is a cross-sectional view of a first transistor according to an embodiment of the present disclosure.

FIG. 4B is a cross-sectional view of a first transistor according to a comparative example.

FIG. 5 is a graph depicting drive voltage ranges depending on the lengths of channel regions according to the embodiment of the present disclosure and the comparative example.

FIG. 6A is a cross-sectional view of a second transistor according to an embodiment of the present disclosure.

FIG. 6B is a cross-sectional view of a second transistor according to a comparative example.

FIG. 7 is a graph depicting voltage-current characteristics according to the embodiment of the present disclosure and the comparative example.

### DETAILED DESCRIPTION

Various changes can be made to the present disclosure, and various embodiments of the present disclosure may be implemented. Thus, specific embodiments are illustrated in the drawings and described as examples herein. However, it should be understood that the present disclosure is not to be construed as necessarily being limited thereto and the present disclosure is intended to cover all modifications, equivalents, and alternatives falling within the spirit and scope of the present disclosure.

In this specification, when it is mentioned that a component (or, a region, a layer, a part, etc.) is referred to as being “on”, “connected to” or “coupled to” another component, this means that the component may be directly on, connected to, or coupled to the other component or one or more third components may be interposed therebetween.

Identical reference numerals may refer to identical components. Additionally, in the drawings, the thicknesses, proportions, and dimensions of components are may be exaggerated for effective description. As used herein, the term “and/or” includes all of one or more combinations defined by related components.

Terms such as first, second, and the like may be used to describe various components, but the components should not necessarily be limited by the terms. The terms may be used for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, a display panel according to an embodiment of the present disclosure will be described with reference to the accompanying drawings.

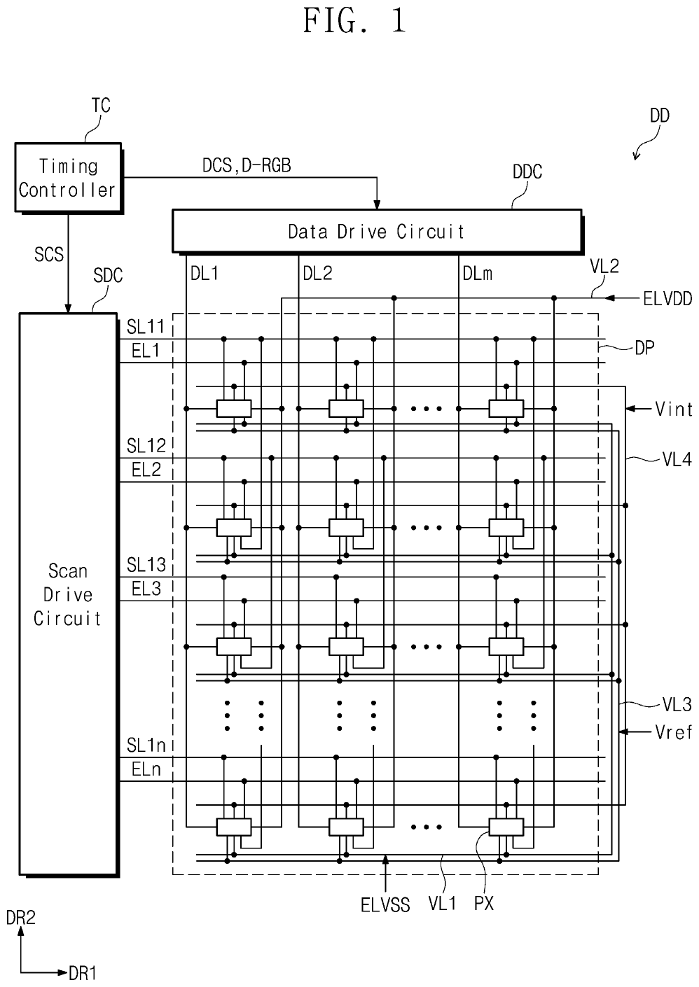

FIG. 1 is a block diagram of a display device DD according to an embodiment of the present disclosure.

The display device DD may be a device that is activated depending on an electrical signal and that displays an image. For example, the display device DD may be a large device such as a television, an electronic billboard, or the like, or may be a small and medium-sized device such as a computer monitor, a mobile phone, a tablet computer, a vehicle or personal navigation unit, a game console, or the like. The display device DD is not necessarily limited to any one embodiment.

Referring to FIG. 1, the display device DD includes a timing controller TC, a scan drive circuit SDC, a data drive circuit DDC, and a display panel DP. Each of the timing controller TC and the data drive circuit DDC may be provided in the form of a drive chip, but may be directly formed on the display panel DP without necessarily being limited thereto.

The timing controller TC may receive an image input signal and may generate an image data signal D-RGB by converting the data format of the image input signal according to the specification of an interface with the data drive circuit DDC. The timing controller TC may receive a control signal and may output a scan control signal SCS and a data control signal DCS. The image input signal and the control signal may be provided from a main controller (or, a graphic processor).

The data drive circuit DDC may receive the data control signal DCS and the image data signal D-RGB from the timing controller TC. The data drive circuit DDC may convert the image data signal D-RGB into data signals and may output the data signals to a plurality of data lines DL1 to DLm. The data signals may be analog voltages corresponding to gray level values of the image data signal D-RGB.

The scan drive circuit SDC may receive the scan control signal SCS from the timing controller TC. The scan control signal SCS may include a vertical start signal to start an operation of the scan drive circuit SDC and a clock signal to determine the time to output signals. The scan drive circuit SDC may generate a plurality of scan signals and may sequentially output the scan signals to corresponding scan signal lines SL11 to SL1n. Furthermore, the scan drive circuit SDC may generate a plurality of emission control signals in response to the scan control signal SCS and may output the plurality of emission control signals to corresponding emission signal lines EL1 to ELn.

Although FIG. 1 illustrates an example that the scan signals and the emission control signals are output from the one scan drive circuit SDC, the present disclosure is not necessarily limited thereto. In the display device DD, according to an embodiment, a drive circuit that generates and outputs scan signals and a drive circuit that generates and outputs emission control signals may be separately formed.

The display panel DP, according to an embodiment of the present disclosure, may be an emissive display panel, but is not necessarily limited thereto. For example, the display panel DP may be an organic light emitting display panel, an inorganic light emitting display panel, or a quantum dot light emitting display panel. An emissive layer of the organic light emitting display panel may include an organic light emitting material, and an emissive layer of the inorganic light emitting display panel may include an inorganic light emitting material. An emissive layer of the quantum dot light emitting display panel may include quantum dots and quantum rods. Hereinafter, it will be exemplified that the display panel DP is an organic light emitting display panel.

The display panel DP may include a plurality of groups of scan signal lines. In FIG. 1, a first group of scan signal lines SL11 to SLIn are illustrated as an example. The display panel DP may include the emission signal lines EL1 to ELn, the data lines DL1 to DLm, a first voltage line VL1, a second voltage line VL2, a third voltage line VL3, a fourth voltage line VL4, and pixels PX. Here, “n” and “m” are representative of positive integers.

The first group of scan signal lines SL11 to SLIn may extend in a first direction DR1 and may be arranged in a second direction DR2. The emission signal lines EL1 to ELn may extend in the first direction DR1 and may be arranged in the second direction DR2. The data lines DL1 to DLm and the first group of scan signal lines SL11 to SLIn may cross each other in a plan view. The data lines DL1 to DLm may extend in the second direction DR2 and may be arranged in the first direction DR1.

The pixels PX are electrically connected to the first group of scan signal lines SL11 to SLIn, the emission signal lines EL1 to ELn, and the data lines DL1 to DLm. However, the types and numbers of signal lines connected to the pixels PX are not necessarily limited thereto. An electrical connection relationship between the signal lines may also be changed.

The first voltage line VL1 may receive a first power voltage ELVSS. The second voltage line VL2 may receive a second power voltage ELVDD. The second power voltage ELVDD may have a higher level than the first power voltage ELVSS. The third voltage line VL3 may receive a reference voltage Vref (hereinafter, referred to as the first voltage). The fourth voltage line VL4 may receive an initialization voltage Vint (hereinafter, referred to as the second voltage). Each of the first voltage Vref and the second voltage Vint may have a lower level than the second power voltage ELVDD. In this embodiment, the second voltage Vint may have a lower level than the first voltage Vref and the first power voltage ELVSS.

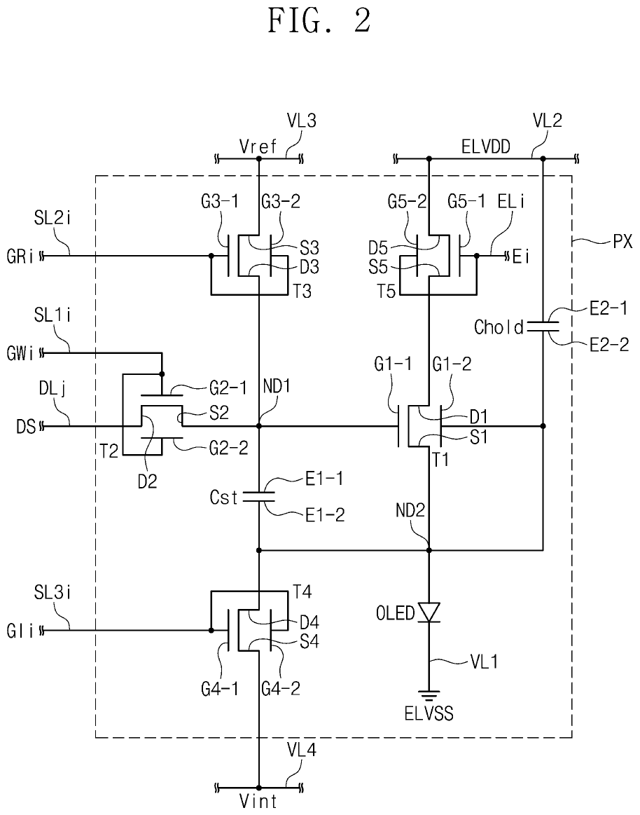

Each of the pixels PX constituting the display panel DP may include a light emitting element OLED (refer to FIG. 2) and a pixel circuit that controls light emission of the light emitting element OLED (refer to FIG. 2). The pixel circuit may include a plurality of transistors and at least one capacitor. At least one of the scan drive circuit SDC and the data drive circuit DDC may include transistors formed through the same process as the pixel circuits of the pixels PX.

The pixels PX may receive the data voltages in response to the scan signals. The pixels PX may display an image by emitting light having luminance corresponding to the data voltages in response to the emission control signals. Light emission time of the pixels PX may be controlled by the emission control signals. Accordingly, the display panel DP may output the image through the pixels PX.

The pixels PX may include a plurality of groups that generate light having different colors. For example, the pixels PX may include red pixels that generate red light, green pixels that generate green light, and blue pixels that generate blue light. Light emitting elements of the red pixels, light emitting elements of the green pixels, and light emitting elements of the blue pixels may be formed of different materials. However, embodiments are not necessarily limited thereto.

FIG. 2 is an equivalent circuit diagram of a pixel PX according to an embodiment of the present disclosure.

FIG. 2 representatively illustrates the pixel PX connected to the i^{th} scan signal line SL1i (or, the first scan signal line) among the first group of scan signal lines SL11 to SLIn (refer to FIG. 1) and connected to the j^{th} data line DLj (or, the first data line) among the data lines DL1 to DLm (refer to FIG. 1). The pixel PX according to an embodiment illustrated in FIG. 2 may be connected to the i^{th} scan signal line SL2i (or, the second scan signal line) among a second group of scan signal lines and may be connected to the i^{th} scan signal line SL3i (or, the third scan signal line) among a third group of scan signal lines. Here, “i” and “j” are natural numbers.

In this embodiment, the pixel circuit may include first to fifth transistors T1 to T5, a storage capacitor Cst (or, a first capacitor), a hold capacitor Chold (or, a second capacitor), and the light emitting element OLED. Each of the first to fifth transistors T1 to T5 may be a transistor having an oxide semiconductor layer. However, without necessarily being limited thereto, at least one of the first to fifth transistors T1 to T5 may be a transistor having a low-temperature polycrystalline silicon (LTPS) semiconductor layer. In this embodiment, it is exemplified that the first to fifth transistors T1 to T5 are N-type transistors. However, without necessarily being limited thereto, at least one of the first to fifth transistors T1 to T5 may be a P-type transistor. In addition, in an embodiment of the present disclosure, at least one of the first to fifth transistors T1 to T5 may be omitted, or an additional transistor may be further included in the pixel PX.

Each of the first to fifth transistors T1 to T5 may include a source, a drain, and a gate. The source, the drain, and the gate may be provided as a source electrode, a drain electrode, and a gate electrode, respectively. The expression “electrically connected between a transistor and a signal line or between a transistor and a transistor” used herein means that an electrode of the transistor is integrally formed with the signal line or connected to the signal line through a connecting electrode.

Although each of the first to fifth transistors T1 to T5 in this embodiment is illustrated as including two gates, at least one transistor may include only one gate. Although upper gates G2-1, G3-1, G4-1, and G5-1 of the second to fifth transistors T2 to T5 are illustrated as being electrically connected to lower gates G2-2, G3-2, G4-2, and G5-2, the present disclosure is not necessarily limited thereto. At least one of the lower gates G2-2, G3-2, G4-2, and G5-2 of the second to fifth transistors T2 to T5 may be a floated electrode.

In this embodiment, the light emitting element OLED may be a light emitting diode. The light emitting element OLED may include a first electrode, a second electrode, and an emissive layer disposed between the first electrode and the second electrode. The first electrode of the light emitting element OLED may be electrically connected to a second node ND2 connected to the first transistor T1, and the second electrode may be electrically connected to the first voltage line VL1 that receives the first power voltage ELVSS.

The first transistor T1 may be electrically connected between the second voltage line VL2 receiving the second power voltage ELVDD and the light emitting element OLED. The first transistor T1 may include a first source S1 electrically connected to the second node ND2, a first drain D1 electrically connected to the second voltage line VL2, and a first upper gate G1-1 electrically connected to a first node ND1. The first transistor T1 may further include a first lower gate G1-2 electrically connected to the second node ND2. The first transistor T1 may control the drive current of the light emitting element OLED depending on the charging capacity of the storage capacitor Cst. In this embodiment, the first transistor T1 may be a drive transistor.

The second transistor T2 may be electrically connected between the data line DLj and the first node ND1. The second transistor T2 may include a second source S2 electrically connected to the first node ND1, a second drain D2 electrically connected to the data line DLj, and the second upper gate G2-1 electrically connected to the first scan signal line SL1i that receives a first scan signal GWi. The second transistor T2 may further include the second lower gate G2-2 electrically connected to the second upper gate G2-1. The second transistor T2 may be turned on depending on the first scan signal GWi and may provide a data voltage to the storage capacitor Cst depending on a data signal DS transferred from the data line DLj. In this embodiment, the second transistor T2 may be a switching transistor.

The third transistor T3 may be electrically connected between the first node ND1 and the third voltage line VL3 that receives the first voltage Vref. The third transistor T3 may include a third drain D3 electrically connected to the first node ND1, a third source S3 electrically connected to the third voltage line VL3, and the third upper gate G3-1 electrically connected to the second scan signal line SL2i that receives a second scan signal GRi. The third transistor T3 may further include the third lower gate G3-2 electrically connected to the third upper gate G3-1. The third transistor T3 may be turned on depending on the second scan signal GRi and may initialize the first node ND1 to the first voltage Vref.

The fourth transistor T4 may be electrically connected between the fourth voltage line VL4 receiving the second voltage Vint and the second node ND2. The fourth transistor T4 may include a fourth drain D4 electrically connected to the second node ND2, a fourth source S4 electrically connected to the fourth voltage line VL4, and the fourth upper gate G4-1 electrically connected to the third scan signal line SL3i that receives a third scan signal GIi. The fourth transistor T4 may further include the fourth lower gate G4-2 electrically connected to the fourth upper gate G4-1. The fourth transistor T4 may be turned on depending on the third scan signal GIi and may initialize the second node ND2 to the second voltage Vint.

The fifth transistor T5 may be electrically connected between the second voltage line VL2 and the first transistor T1. The fifth transistor T5 may include a fifth drain D5 electrically connected to the second voltage line VL2, a fifth source S5 to be electrically connected to the first drain D1, and the fifth upper gate G5-1 electrically connected to an emission signal line ELi that receives an emission signal Ei. The fifth transistor T5 may further include the fifth lower gate G5-2 electrically connected to the fifth upper gate G5-1. The fifth transistor T5 may be turned on depending on the emission signal Ei, and the first transistor T1 may provide current corresponding to a voltage value stored in the storage capacitor Cst to the light emitting element OLED. The light emitting element OLED may emit light with a luminance corresponding to the data signal DS.

The storage capacitor Cst may be electrically connected between the first node ND1 and the second node ND2. The storage capacitor Cst may include a first electrode E1-1 electrically connected to the first node ND1 and a second electrode E1-2 electrically connected to the second node ND2.

The hold capacitor Chold may be electrically connected between the second voltage line VL2 and the second node ND2. The hold capacitor Chold may include a first electrode E2-1 electrically connected to the second voltage line VL2 and a second electrode E2-2 electrically connected to the second node ND2.

Each of the pixels PX illustrated in FIG. 1 may include a pixel circuit having the same configuration as the equivalent circuit diagram of the pixel PX illustrated in FIG. 2. However, the numbers of transistors and capacitors included in the pixel PX or a connecting structure thereof may be changed in various ways.

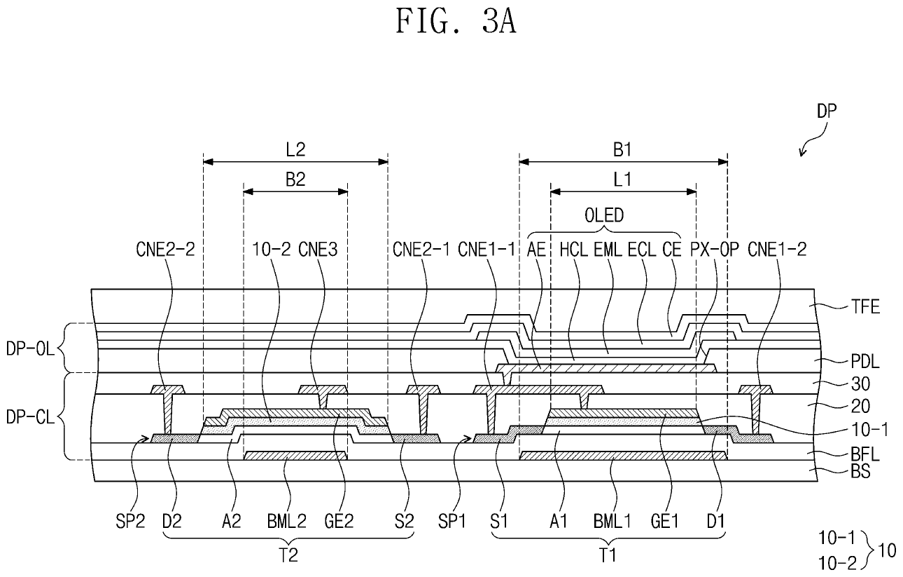

FIGS. 3A to 3C are cross-sectional views of a display panel DP according to an embodiment of the present disclosure.

Referring to FIGS. 3A to 3C, the display panel DP may include a base substrate BS, a circuit element layer DP-CL, a display element layer DP-OL, and an encapsulation layer TFE. The display panel DP may further include functional layers such as an anti-reflection layer, a refractive index control layer, and/or the like.

Each of the pixels PX (refer to FIG. 1) of the display panel DP may include transistors disposed in the circuit element layer DP-CL and a light emitting element OLED disposed in the display element layer DP-OL and electrically connected to the transistors. FIGS. 3A to 3C illustrate sections of the first transistor T1 and the second transistor T2 among the transistors constituting the pixel PX (refer to FIG. 2) and the light emitting element OLED.

The base substrate BS may provide a base surface on which the circuit element layer DP-CL is disposed. The base substrate BS may include a glass substrate, a metal substrate, a polymer substrate, or an organic/inorganic composite substrate.

In an embodiment, the base substrate BS may include at least one synthetic resin layer. The synthetic resin layer included in the base substrate BS may include an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, and/or a perylene-based resin.

The base substrate BS may further include a barrier layer that defines an upper surface of the base substrate BS. The barrier layer may include at least one inorganic layer that prevents infiltration of foreign matter from the outside. For example, the barrier layer may include aluminum oxide, titanium oxide, silicon oxide, silicon nitride, silicon oxy-nitride, zirconium oxide, and/or hafnium oxide.

The circuit element layer DP-CL may be disposed on the base substrate BS. The circuit element layer DP-CL may include the transistors T1 and T2 constituting the pixel circuit of the pixel PX (refer to FIG. 2) and a plurality of insulating layers BFL, 10, 20, and 30. The plurality of insulating layers BFL, 10, 20, and 30 may include the buffer layer BFL and the first to third insulating layers 10, 20, and 30. However, the number of insulating layers included in the circuit element layer DP-CL and a stacked structure thereof are not necessarily limited to the illustrated embodiment.

A semiconductor pattern and a conductive pattern of the circuit element layer DP-CL may be formed by forming an insulating layer, a semiconductor layer, and a conductive layer on the base substrate BS through coating or deposition and thereafter making the insulating layer, the semiconductor layer, and the conductive layer subject to patterning by performing a photolithography process a plurality of times. The cross-sectional structure of the circuit element layer DP-CL illustrated in FIGS. 3A to 3C may vary depending on a manufacturing process of the circuit element layer DP-CL or the configuration of the pixel circuit.

The first transistor T1 may include a first conductive pattern BML1, a first semiconductor pattern SP1, and a first gate electrode GE1. The first semiconductor pattern SP1 may include a first source region S1, a first channel region A1, and a first drain region D1.

The second transistor T2 may include a second conductive pattern BML2, a second semiconductor pattern SP2, and a second gate electrode GE2. The second semiconductor pattern SP2 may include a second source region S2, a second channel region A2, and a second drain region D2.

The buffer layer BFL may be disposed on the base substrate BS. The buffer layer BFL may cover the first conductive pattern BML1 and the second conductive pattern BML2. The buffer layer BFL may increase bonding forces between the base substrate BS and the semiconductor patterns SP1 and SP2 and/or the conductive patterns BML1 and BML2. The buffer layer BFL may include at least one inorganic layer. For example, the buffer layer BFL may include aluminum oxide, titanium oxide, silicon oxide, silicon nitride, silicon oxy-nitride, zirconium oxide, and/or hafnium oxide.

The first and second semiconductor patterns SP1 and SP2 may be disposed on the buffer layer BFL. In an embodiment, the first semiconductor pattern SP1 of the first transistor T1 and the second semiconductor pattern SP2 of the second transistor T2 may be disposed on the same layer. The first semiconductor pattern SP1 and the second semiconductor pattern SP2 may be simultaneously formed through the same process step.

The first and second semiconductor patterns SP1 and SP2 may include a metal oxide semiconductor material. Since the first and second semiconductor patterns SP1 and SP2 include the metal oxide semiconductor material, electron mobility in the transistors may be increased, and leakage current may be reduced.

The metal oxide semiconductor material may be crystalline or non-crystalline oxide. For example, each of the first and second semiconductor patterns SP1 and SP2 may include metal oxide of zinc (Zn), indium (In), gallium (Ga), tin (Sn), or titanium (Ti), or may include metal such as zinc (Zn), indium (In), gallium (Ga), tin (Sn), or titanium (Ti) and a mixture of oxide thereof. In an embodiment, the metal oxide semiconductor material may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO). However, without being limited thereto. The first and second semiconductor patterns SP1 and/or SP2 may include a silicon semiconductor material.

The first and second semiconductor patterns SP1 and SP2 may include a plurality of regions having different electrical properties. For example, the first and second semiconductor patterns SP1 and SP2 may include a plurality of regions distinguished from one another depending on whether metal oxide is reduced. A region where metal oxide is reduced (hereinafter, referred to as the reduced region) may have a higher electrical conductivity than a region where metal oxide is not reduced (hereinafter, referred to as the non-reduced region). The reduced region may serve as a source region (e.g., the first and second source regions S1 and S2), a drain region (e.g., the first and second drain regions D1 and D2), or a signal transmission region of a transistor. The non-reduced region may correspond to a channel region (e.g., the first and second channel regions A1 and A2) of the transistor.

The source regions S1 and S2 or the drain regions D1 and D2 of the transistors T1 and T2 may themselves be the sources or drains of the transistors described with reference to FIG. 2. Alternatively, the sources or drains of the transistors T1 and T2 may include the source regions S1 and S2 or the drain regions D1 and D2 of the semiconductor patterns SP1 and SP2 and conductive electrodes connected thereto.

The first source region S1 and the first drain region D1 may be spaced apart from each other with the first channel region A1 interposed therebetween. For example, the first source region S1 and the first drain region D1 may extend from the first channel region A1 in opposite directions. The second source region S2 and the second drain region D2 may extend from the second channel region A2 in opposite directions and may be spaced apart from each other with the second channel region A2 interposed therebetween.

The first conductive pattern BML1 may be spaced apart from the first channel region A1 with the buffer layer BFL interposed therebetween in the thickness direction. The second conductive pattern BML2 may be spaced apart from the second channel region A2 with the buffer layer BFL interposed therebetween in the thickness direction.

The first conductive pattern BML1 overlapping the first channel region A1 may correspond to the first lower gate G1-2 (refer to FIG. 2). The first gate electrode GE1 overlapping the first channel region A1 may correspond to the first upper gate G1-1 (refer to FIG. 2). The second conductive pattern BML2 overlapping the second channel region A2 may correspond to the second lower gate G2-2 (refer to FIG. 2). The second gate electrode GE2 overlapping the second channel region A2 may correspond to the second upper gate G2-1 (refer to FIG. 2).

The first gate electrode GE1 may define the first channel region A1 of the first transistor T1, and the second gate electrode GE2 may define the second channel region A2 of the second transistor T2. For example, the length of the first channel region A1 of the first transistor T1 may be determined to correspond to the length of the gate electrode GE1, and the length of the second channel region A2 of the second transistor T2 may be determined to correspond to the length of the second gate electrode GE2.

The first conductive pattern BML1 and the second conductive pattern BML2 may have a function of a light blocking pattern. The first conductive pattern BML1 and the second conductive pattern BML2 may be disposed under the first channel region A1 of the first transistor T1 and the second channel region A2 of the second transistor T2, respectively, and may block ambient light incident toward the semiconductor patterns SP1 and SP2. Accordingly, the first conductive pattern BML1 and the second conductive pattern BML2 may prevent external light from changing the voltage-current characteristics of the first transistor T1 and the second transistor T2.

The first insulating layer 10 may be disposed on the buffer layer BFL. In an embodiment, the first insulating layer 10 may include a plurality of insulating patterns 10-1 and 10-2 spaced apart from each other. FIGS. 3A to 3C illustrate the first and second insulating patterns 10-1 and 10-2 as an example. The first insulating pattern 10-1 may be disposed on the first channel region A1 to overlap the first channel region A1, and the second insulating pattern 10-2 may be disposed on the second channel region A2 to overlap the second channel region A2. The first and second insulating patterns 10-1 and 10-2 may be formed by making one insulating layer subject to patterning. However, without necessarily being limited thereto, the first insulating layer 10 may be formed of an integral film covering the semiconductor patterns SP1 and SP2.

The first insulating layer 10 may include at least one inorganic layer. For example, the first insulating layer 10 may include aluminum oxide, titanium oxide, silicon oxide, silicon nitride, silicon oxy-nitride, zirconium oxide, and/or hafnium oxide. However, the material of the first insulating layer 10 is not necessarily limited to the aforementioned examples.

The first gate electrode GE1 and the second gate electrode GE2 may be disposed over the first semiconductor pattern SP1 and the second semiconductor pattern SP2, respectively. The first gate electrode GE1 may be disposed over the first channel region A1 and may overlap the first channel region A1. The second gate electrode GE2 may be disposed over the second channel region A2 and may overlap the second channel region A2.

The first insulating pattern 10-1 may be disposed between the first gate electrode GE1 and the first channel region A1. For example, the first gate electrode GE1 may be spaced apart from the first channel region A1 with the first insulating pattern 10-1 interposed therebetween in the thickness direction. The second insulating pattern 10-2 may be disposed between the second gate electrode GE2 and the second channel region A2. For example, the second gate electrode GE2 may be spaced apart from the second channel region A2 with the second insulating pattern 10-2 interposed therebetween in the thickness direction. The first gate electrode GE1 and the second gate electrode GE2 may serve as masks for forming the first insulating pattern 10-1 and the second insulating pattern 10-2, respectively.

The first gate electrode GE1 and the second gate electrode GE2 may be disposed on the same first insulating layer 10. The first gate electrode GE1 and the second gate electrode GE2 may be simultaneously formed through the same process step. For example, the first gate electrode GE1 and the second gate electrode GE2 may be formed by making one metal layer subject to patterning. The first gate electrode GE1 and the second gate electrode GE2 may include the same material. However, embodiments of the first gate electrode GE1 and the second gate electrode GE2 are not necessarily limited thereto, and the first gate electrode GE1 and the second gate electrode GE2 may be disposed on different layers.

The second insulating layer 20 may cover the first and second semiconductor patterns SP1 and SP2 and the first and second gate electrodes GE1 and GE2 and may be disposed on the buffer layer BFL. The second insulating layer 20 may cover the first source region S1 and the first drain region D1 of the first transistor T1 and the second source region S2 and the second drain region D2 of the second transistor T2. The first channel region A1 may be spaced apart from the second insulating layer 20 with the first insulating pattern 10-1 and the first gate electrode GE1 interposed therebetween. The second channel region A2 may be spaced apart from the second insulating layer 20 with the second insulating pattern 10-2 and the second gate electrode GE2 interposed therebetween.

The circuit element layer DP-CL may include connecting electrodes CNE1-1, CNE1-2, CNE2-1, CNE2-2, and CNE3. The connecting electrodes CNE1-1, CNE1-2, CNE2-1, CNE2-2, and CNE3 may be disposed on the second insulating layer 20. Although FIGS. 3A to 3C illustrate the connecting electrodes CNE1-1, CNE1-2, CNE2-1, CNE2-2, and CNE3 disposed on the same layer, embodiments are not necessarily limited thereto, and some of the connecting electrodes CNE1-1, CNE1-2, CNE2-1, CNE2-2, and CNE3 may be disposed on different layers. For example, the circuit element layer DP-CL may further include an additional insulating layer disposed between the second insulating layer 20 and the third insulating layer 30, and some of the connecting electrodes CNE1-1, CNE1-2, CNE2-1, CNE2-2, and CNE3 may be disposed on the additional insulating layer.

The connecting electrodes CNE1-1, CNE1-2, CNE2-1, CNE2-2, and CNE3 may include first connecting electrodes CNE1-1 and CNE1-2, second connecting electrodes CNE2-1 and CNE2-2, and a third connecting electrode CNE3.

The first connecting electrode CNE1-1, which is one of the first connecting electrodes CNE1-1 and CNE1-2, may be connected to the first source region S1 through a contact hole penetrating the second insulating layer 20. The first connecting electrode CNE1-2, which is the other one of the first connecting electrodes CNE1-2 and CNE1-2, may be connected to the first drain region D1 through a contact hole penetrating the second insulating layer 20.

The first connecting electrode CNE1-1 connected to the first source region S1 may extend in a plan view and may overlap a portion of the first gate electrode GE1. The first connecting electrode CNE1-1 may be connected to the first gate electrode GE1 through a contact hole penetrating the second insulating layer 20. Accordingly, the first source region S1 and the first gate electrode GE1 may be electrically connected through the first connecting electrode CNE1-1. In this embodiment, in the first transistor T1 corresponding to the drive transistor, the first gate electrode GE1 corresponding to the first upper gate G1-1 (refer to FIG. 2) and the first source region S1 may be electrically connected. Accordingly, the drive voltage range of the first transistor T1 (e.g., the drive transistor) may be widened. Detailed description thereabout will be given below.

The second connecting electrode CNE2-1, which is one of the second connecting electrodes CNE2-1 and CNE2-2, may be connected to the second source region S2 through a contact hole penetrating the second insulating layer 20. The second connecting electrode CNE2-2, which is the other one of the second connecting electrodes CNE2-1 and CNE2-2, may be connected to the second drain region D2 through a contact hole penetrating the second insulating layer 20.

The second gate electrode GE2 of the second transistor T2, according to the embodiment illustrated in FIG. 3A, may be electrically connected to the second conductive pattern BML2. For example, the second upper gate G2-1 (refer to FIG. 2) corresponding to the second gate electrode GE2 of the second transistor T2 and the second lower gate G2-2 (refer to FIG. 2) corresponding to the second conductive pattern BML2 may be electrically connected to each other. For example, the third connecting electrode CNE3 may be connected to the second gate electrode GE2 through a contact hole penetrating the second insulating layer 20. The third connecting electrode CNE3 may extend in a plan view and may be connected to the second conductive pattern BML2. For example, although not illustrated in FIG. 3A, the second gate electrode GE2 and the second conductive pattern BML2 may be electrically connected to each other through the third connecting electrode CNE3. Accordingly, in an embodiment, the second transistor T2 may have a dual gate structure.

However, without necessarily being limited thereto, the second conductive pattern BML2 may be a floated electrode as in the embodiment illustrated in FIG. 3B. For example, the third connecting electrode CNE3 of FIG. 3A may be omitted, and the second gate electrode GE2 and the second conductive pattern BML2 may overlap each other in a plan view, but may be electrically insulated from each other. Accordingly, in an embodiment, the second transistor T2 may have a single gate structure.

When the second transistor T2 having the dual gate structure is compared with the second transistor T2 having the single gate structure, both an upper portion and a lower portion of the second channel region A2 of the second transistor T2 having the dual gate structure may serve as a passage through which electrons move. Accordingly, electron mobility of the second transistor T2 having the dual gate structure may be increased. The structure of the second transistor T2 included in the display panel DP may vary depending on characteristics of a device to which the display panel DP is applied.

The third insulating layer 30 may cover the connecting electrodes CNE1-1, CNE1-2, CNE2-1, CNE2-2, and CNE3 and may be disposed on the second insulating layer 20. Each of the second insulating layer 20 and the third insulating layer 30 may include an inorganic layer and/or an organic layer and may have a single-layer structure or a multi-layer structure. The third insulating layer 30 may include an organic layer disposed at the top thereof. Since the third insulating layer 30 includes the organic layer, the third insulating layer 30 may cover corrugated upper surfaces of components disposed under the third insulating layer 30 and may provide a flat upper surface.

The display element layer DP-OL may be disposed on the circuit element layer DP-CL. The display element layer DP-OL may include the light emitting element OLED and a pixel defining layer PDL. The light emitting element OLED may include a first electrode AE, a second electrode CE, a hole control layer HCL, an electron control layer ECL, and an emissive layer EML. In an embodiment, the first electrode AE of the light emitting element OLED may be an anode, and the second electrode CE may be a cathode.

The first electrode AE of the light emitting element OLED and the pixel defining layer PDL may be disposed on the third insulating layer 30. The first electrode AE may be connected to the first connecting electrode CNE1-1 through a contact hole penetrating the third insulating layer 30 and may be electrically connected to the first source region S1 through the first connecting electrode CNE1-1.

A light emitting opening PX-OP for exposing at least a portion of the first electrode AE may be defined in the pixel defining layer PDL. In this embodiment, a portion of the first electrode AE exposed by the light emitting opening PX-OP may correspond to an emissive region.

The pixel defining layer PDL may include a polymer resin and may further include an inorganic material included in the polymer resin. The pixel defining layer PDL, according to an embodiment, may have a predetermined color. For example, the pixel defining layer PDL may include a base resin and a black pigment and/or a black dye mixed with the base resin. However, embodiments of the pixel defining layer PDL are not necessarily limited thereto.

The hole control layer HCL may be disposed on the first electrode AE and the pixel defining layer PDL. The hole control layer HCL may be commonly disposed for the pixels PX (refer to FIG. 1). The hole control layer HCL may include a hole injection layer, a hole transport layer, and/or an electron blocking layer.

The emissive layer EML may be disposed on the hole control layer HCL. The emissive layer EML may include an organic material and/or an inorganic material. The emissive layer EML may be disposed in a pattern in a region corresponding to the light emitting opening PX-OP. The emissive layer EML may generate any one of red light, green light, and blue light. However, without necessarily being limited thereto, the emissive layer EML may be commonly disposed for the pixels PX (refer to FIG. 1) and may generate blue light or white light.

The electron control layer ECL may be disposed on the emissive layer EML and the hole control layer HCL. The electron control layer ECL may be commonly disposed for the pixels PX (refer to FIG. 1). The electron control layer ECL may include an electron injection layer, an electron transport layer, and/or a hole blocking layer.

The second electrode CE may be disposed on the electron control layer ECL. The second electrode CE may be commonly disposed for the pixels PX (refer to FIG. 1).

The first power voltage ELVSS (refer to FIG. 2) may be applied to the second electrode CE, and the second power voltage ELVDD (refer to FIG. 2) may be applied to the first electrode AE. Holes and electrons injected into the emissive layer EML may be combined to form excitons, and the light emitting element OLED may emit light as the excitons transition to a ground state.

The encapsulation layer TFE may be disposed on the display element layer DP-OL and may seal the light emitting element OLED. The encapsulation layer TFE may include a plurality of thin films. For example, the encapsulation layer TFE may include inorganic films and an organic film disposed between the inorganic films. The thin films of the encapsulation layer TFE may be disposed to increase the optical efficiency of the light emitting element OLED or protect the light emitting element OLED. The inorganic films may protect the light emitting element OLED from moisture and/or oxygen, and the organic film may protect the light emitting element OLED from foreign matter such as dust particles.

In an embodiment of the present disclosure, the lengths of the conductive patterns BML1 and BML2 overlapping the semiconductor patterns SP1 and SP2 may be adjusted depending on functions of the transistors T1 and T2. Accordingly, characteristics required for the respective transistors T1 and T2 may be satisfied, and the drive reliability of the transistors T1 and T2 and the reliability of the display panel DP may be increased.

The length B1 of the first conductive pattern BML1 disposed to correspond to the first channel region A1 may be substantially the same as or greater than the length of the first channel region A1. For example, the length of the first channel region A1 overlapping the first conductive pattern BML1 may be smaller than or equal to the length B1 of the first conductive pattern BML1. For example, in a plan view, the entire first channel region A1 may overlap the first conductive pattern BML1. Accordingly, in a plan view, the first conductive pattern BML1 may cover a lower region of the first channel region A1.

The length B1 of the first conductive pattern BML1 may be greater than or equal to the length L1 of the first gate electrode GE1. In a plan view, the length B1 of the first conductive pattern BML1 may be greater than the length of the first gate electrode GE1, and in a plan view, outer ends of the first conductive pattern BML1 may be spaced apart from the first gate electrode GE1. Accordingly, when viewed from below the display panel DP, outer ends of the first gate electrode GE1 may overlap the first conductive pattern BML1.

The length B2 of the second conductive pattern BML2 disposed to correspond to the second channel region A2 may be smaller than the length of the second channel region A2. For example, the length of the second conductive pattern BML2 overlapping the second channel region A2 may be smaller than or equal to the length of the second channel region A2. For example, in a plan view, the second conductive pattern BML2 may overlap only a portion of the second channel region A2. In a plan view, an outer portion of the second channel region A2 might not overlap the second conductive pattern BML2. In a plan view, outer ends of the second conductive pattern BML2 may overlap the second channel region A2 and may be covered by the second channel region A2.

The length B2 of the second conductive pattern BML2 may be smaller than the length L2 of the second gate electrode GE2. In a plan view, the length L2 of the second gate electrode GE2 may be greater than the length of the second conductive pattern BML2, and the outer ends of the second conductive pattern BML2 may overlap the second gate electrode GE2 and may be covered by the second gate electrode GE2. For example, in a plan view, the outer ends of the second conductive pattern BML2 may be located more inward than outer ends of the second gate electrode GE2.

The second channel region A2 may extend beyond the outer ends of the second conductive pattern BML2, and the second channel region A2 may cover the second conductive pattern BML2 having the short length B2. Accordingly, the second channel region A2 may have a stepped shape. Portions where steps are formed in the second channel region A2 may correspond to the outer ends of the second conductive pattern BML2. Since the second channel region A2 has the stepped shape, the substantial length of the second channel region A2 may be increased, compared to that of a channel region formed flat based on the same area.

The second gate electrode GE2 may be disposed over the second channel region A2 and may have a shape corresponding to the stepped shape of the second channel region A2. For example, the second gate electrode GE2 may have a stepped shape to correspond to the second channel region A2 and may cover the second channel region A2. Since the second gate electrode GE2 covers the second channel region A2 while forming steps, diffusion of hydrogen generated in a forming process of the second insulating layer 20 into the second channel region A2 may be blocked, and the second channel region A2 may maintain semiconductor characteristics.

Although FIGS. 3A and 3B illustrate the second conductive pattern BML2 integrally formed under the second channel region A2, embodiments are not necessarily limited thereto. Referring to FIG. 3C, the second conductive pattern BML2 may include a plurality of patterns P1 and P2 that are disposed under the second channel region A2 so as to be spaced apart from each other. The length of each of the patterns P1 and P2 may be smaller than the length L2 of the integrated second conductive pattern BML2 illustrated in FIG. 3A.

The sum of the lengths of the patterns P1 and P2 disposed to correspond to the second channel region A2 may be smaller than the length of the second channel region A2. Each of the patterns P1 and P2 may overlap only a portion of the second channel region A2. For example, in a plan view, the separation space between the patterns P1 and P2 may overlap the second channel region A2. In a plan view, outer ends of the patterns P1 and P2 may overlap the second channel region A2 and may be covered by the second channel region A2.

The sum of the lengths of the patterns P1 and P2 may be smaller than the length L2 of the second gate electrode GE2. The gap B2 between the outer ends of the patterns P1 and P2 may be smaller than the length L2 of the second gate electrode GE2. In a plan view, the second gate electrode GE2 may overlap and cover the patterns P1 and P2 and the separation space between the patterns P1 and P2. The outer ends of the patterns P1 and P2 may overlap the second gate electrode GE2 and may be covered by the second gate electrode GE2.

Since the second channel region A2 covers the patterns P1 and P2 spaced apart from each other in a region corresponding to the second channel region A2, the second channel region A2 may have a stepped shape. Portions where steps are formed in the second channel region A2 may correspond to the outer ends of the patterns P1 and P2. Since the second conductive pattern BML2 is formed of the patterns P1 and P2 spaced apart from each other, more steps may be formed in the second channel region A2. Accordingly, when compared to the length of a channel region formed flat based on the same area, the substantial length of the second channel region A2 may be increased.

The second gate electrode GE2 may be disposed over the second channel region A2 and may have a shape corresponding to the stepped shape of the second channel region A2. For example, the second gate electrode GE2 may have a stepped shape corresponding to the stepped shape of the second channel region A2 and may cover the second channel region A2. Accordingly, the second gate electrode GE2 may block diffusion of hydrogen generated in the forming process of the second insulating layer 20 into the second channel region A2.

The shape of the second conductive pattern BML2 or the number of patterns P1 and P2 included in the second conductive pattern BML2 is not necessarily limited to any one embodiment as long as the second conductive pattern BML2 is formed to have a length smaller than the length of the second channel region A2 and the length L2 of the second gate electrode GE2.

The lengths of the channel regions A1 and A2 may be differently designed depending on roles and characteristics of the transistors. The length of the first channel region A1 of the first transistor T1, which is a drive transistor affecting grayscale expression, may be greater than the length of the second channel region A2 of the second transistor T2, which is a switching transistor involved in On/Off.

The drive voltage range of the first transistor T1 (or, the drive transistor) may vary depending on the length of the first channel region A1. For example, when the first channel region A1 has a length of about 7 μm to about 10 μm, the first transistor T1 (or, the drive transistor) may have a drive voltage range required for the display panel DP. However, the length of the first channel region A1 is not necessarily limited to the numerical example.

The length of the second channel region A2 may be smaller than the length of the first channel region A1. Accordingly, the second transistor T2 (or, the switching transistor) may specialize in an On/Off function. For example, the length of the second channel region A2 of the second transistor T2 may be about 4 μm. However, the length of the second channel region A2 is not necessarily limited to the numerical example.

Since the first conductive pattern BML1 covers the lower region of the first channel region A1, the length B1 of the first conductive pattern BML1 may be greater than the length of the first channel region A1. Since the second conductive pattern BML2 is covered by the second channel region A2, the length B2 of the second conductive pattern BML2 may be smaller than the length of the second channel region A2. Depending on characteristics of the transistors T1 and T2, the length of the first channel region A1 may be greater than the length of the second channel region A2. Accordingly, the length B1 of the first conductive pattern BML1 may be greater than the length B2 of the second conductive pattern BML2.

Hydrogen may be supplied to the first source region S1 and the first drain region D1 in the process of forming the second insulating layer 20. In particular, when a silicon nitride layer is formed in the second insulating layer 20, the forming process of the second insulating layer 20 may maintain high hydrogen partial pressure, and a large amount of hydrogen may be provided to the first semiconductor pattern SP1. The hydrogen may function as a carrier to reduce the resistances of the first source region S1 and the first drain region D1 of the first semiconductor pattern SP1.

However, when hydrogen generated in the forming process of the second insulating layer 20 is diffused into the relatively short second channel region A2, a carrier concentration may be higher than necessary, and therefore the second transistor T2 may be short-circuited. However, since the second channel region A2, according to the embodiment of the present disclosure, has the stepped shape, the actual length of the second channel region A2 may be increased. Accordingly, even when hydrogen is diffused into a portion of the second channel region A2, the effective length of the second channel region A2 may be prevented from being shorter than a design value, and the second transistor T2 may be prevented from being short-circuited. In addition, since the second gate electrode GE2 has the stepped shape corresponding to the shape of the second channel region A2, diffusion of hydrogen generated in the forming process of the second insulating layer 20 into the second channel region A2 may be easily blocked. Accordingly, a difference between the effective length of the second channel region A2 and the actual length of the second channel region A2 may be reduced.

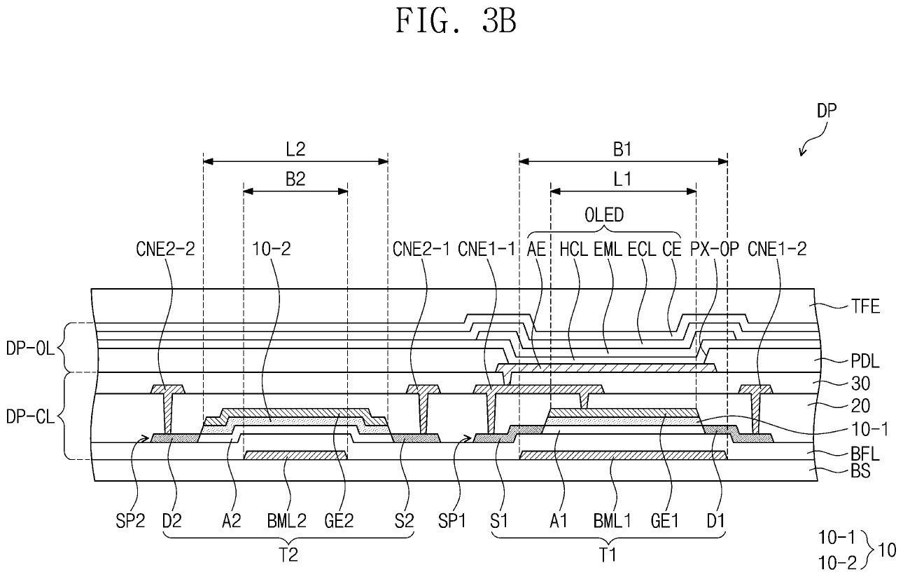

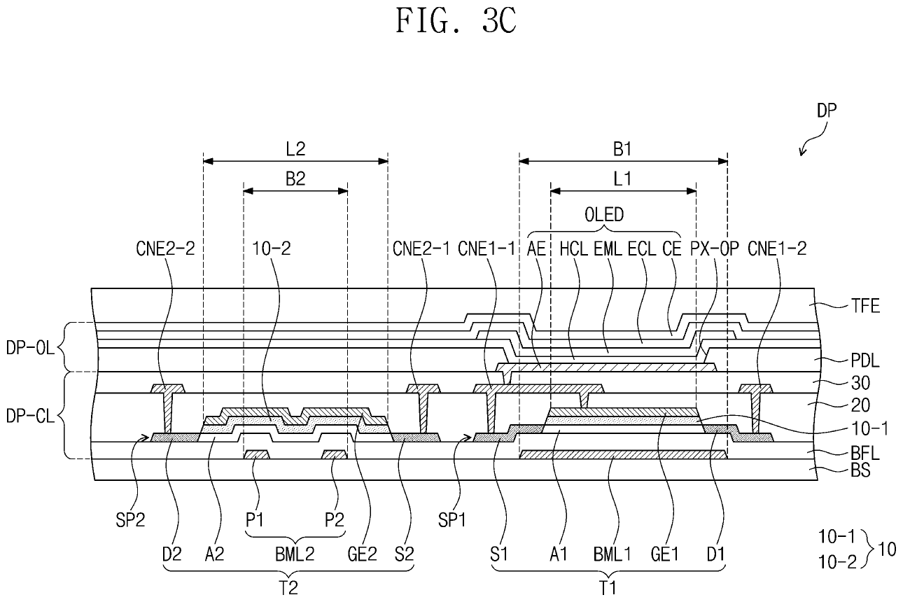

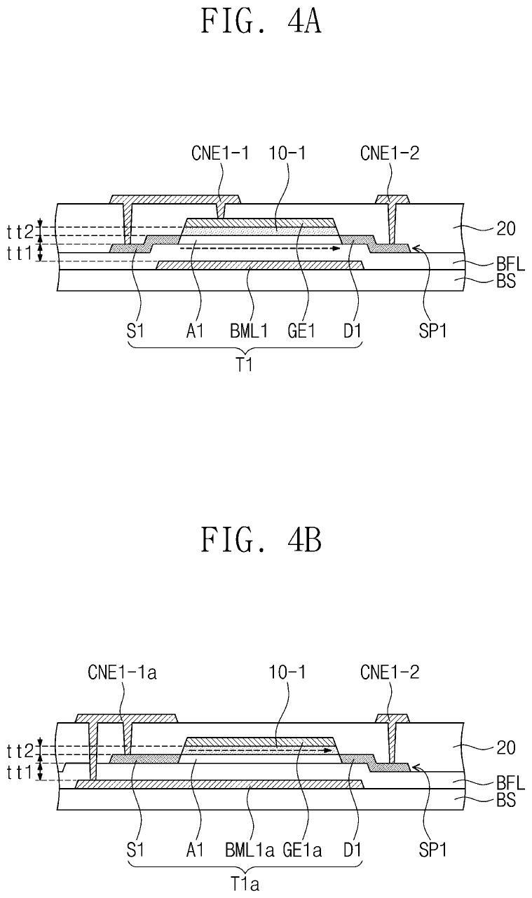

FIG. 4A is a cross-sectional view of a first transistor T1 according to an embodiment of the present disclosure. FIG. 4B is a cross-sectional view of a first transistor T1a according to a comparative example. FIG. 5 is a graph depicting drive voltage ranges depending on the lengths of channel regions according to the embodiment of the present disclosure and the comparative example. The description given above with reference to FIG. 3A may be applied to the first transistor T1 of FIG. 4A.

Referring to FIG. 4A, the first transistor T1 may have a bottom gate structure. The first conductive pattern BML1 disposed under the first channel region A1 may serve as a gate electrode of the first transistor T1. Accordingly, the lower region of the first channel region A1 may act as the main channel region, and thus the effective length of the first channel region A1 may be increased.

Referring to FIG. 4B, the first transistor T1a according to the comparative example may have a top gate structure. A first conductive pattern BML1a may be electrically connected to a first source region S1 through a first connecting electrode CNE1-1a. A first gate electrode GE1a disposed over the first channel region A1 may serve as a gate electrode of the first transistor T1a. Accordingly, an upper region of the first channel region A1 may act as the main channel region.

When the first transistor T1, according to the embodiment of the present disclosure, is compared with the first transistor T1a, according to the comparative example, the effective length of the first channel region A1 of the first transistor T1 may be increased. As the effective length of the first channel region A1 of the first transistor T1 is increased, the drive reliability of the first transistor T1 may be increased. In addition, the drive voltage range of the first transistor T1 corresponding to the drive transistor may be increased.

Referring to FIG. 4A, the buffer layer BFL may be disposed between the first channel region A1 and the first conductive pattern BML1 corresponding to the first lower gate G1-2 (refer to FIG. 2) in the thickness direction. For example, the first conductive pattern BML1 and the first channel region A1 may be spaced apart from each other with the buffer layer BFL interposed therebetween in the thickness direction. The buffer layer BFL disposed between the first conductive pattern BML1 serving as the gate electrode and the first channel region A1 may serve as a gate insulating film of the first transistor T1.

Referring to FIG. 4B, a first insulating pattern 10-1 may be disposed between the first channel region A1 and the first gate electrode GE1a corresponding to the upper gate in the thickness direction. For example, the first gate electrode GE1a and the first channel region A1 may be spaced apart from each other with the first insulating pattern 10-1 interposed therebetween in the thickness direction. The first insulating pattern 10-1 disposed between the first gate electrode GE1a serving as the gate electrode and the first channel region A1 may serve as a gate insulating film of the first transistor T1a.

Referring to FIGS. 4A and 4B, the thickness tt1 of the buffer layer BFL may be greater than the thickness tt2 of the first insulating pattern 10-1. As the buffer layer BFL corresponding to the gate insulating film of the first transistor T1, according to the embodiment, has the thickness tt1 that is greater than the thickness tt2 of the first insulating pattern 10-1 corresponding to the gate insulating film of the first transistor T1a, according to the comparative example, a field effect may be reduced, and the reliability of the first transistor T1 may be increased.

Referring to FIG. 5, drive voltage ranges depending on the lengths of the first channel regions A1 (refer to FIGS. 4A and 4B) according to embodiment 1 (E1) and comparative example 1 (C1) are illustrated. A drive transistor of embodiment 1 (E1) corresponds to the first transistor T1 of FIG. 4A, and a drive transistor of comparative example 1 (C1) corresponds to the first transistor T1a of FIG. 4B.

Referring to FIGS. 4A, 4B, and 5, the drive voltage ranges may be increased as the lengths of the first channel regions A1 of embodiment 1 (E1) and comparative example 1 (C1) are increased. Based on the same length of the first channel regions A1, the degree of increase in the driving voltage range of the drive transistor (or, the first transistor T1) of embodiment 1 (E1) may be higher than the degree of increase in the driving voltage range of the drive transistor (or, the first transistor T1a) of comparative example 1 (C1).

In a case in which the drive voltage ranges of the drive transistors are narrow, there may be a limitation in that a gray level voltage has to be precisely controlled to express gray levels. However, as the drive voltage range of the drive transistor (or, the first transistor t1) of embodiment 1 (E1) is increased, the color gradation expression characteristics of the display panel DP may be increased.

The drive voltage range of the drive transistor (or, the first transistor T1) needs to be secured above a predetermined value to express a required color gradation. For example, a drive voltage range of 1.3 V or more needs to be secured for the drive reliability of the drive transistor. Since the first transistor T1 of embodiment 1 (E1) has a bottom gate structure, the first transistor T1 may have an increased drive voltage range, compared to the first transistor T1a of comparative example 1 (C1). When the first channel region A1 of the first transistor T1 of embodiment 1 (E1) has a length of about 7 μm or more, the first transistor T1 may have a drive voltage range required to secure drive reliability. In contrast, even though the first channel region A1 of the first transistor T1a of comparative example 1 (C1) has a length of about 10 μm or more, the drive voltage range of the first transistor T1a may be smaller than that of the first transistor T1 of embodiment 1 (E1).

The first transistor T1 may have hysteresis characteristics in which a drive current by a signal applied in a frame drive period is affected by a signal applied in the previous frame drive period. As the drive voltage range of the first transistor T1 of the present disclosure is increased, the hysteresis characteristics may be minimized, and a change in luminance due to the hysteresis characteristics may be minimized. Accordingly, the display quality of the display panel DP may be increased.

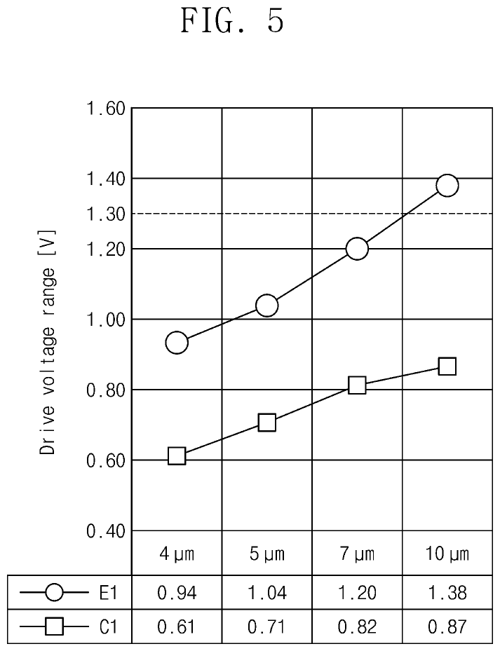

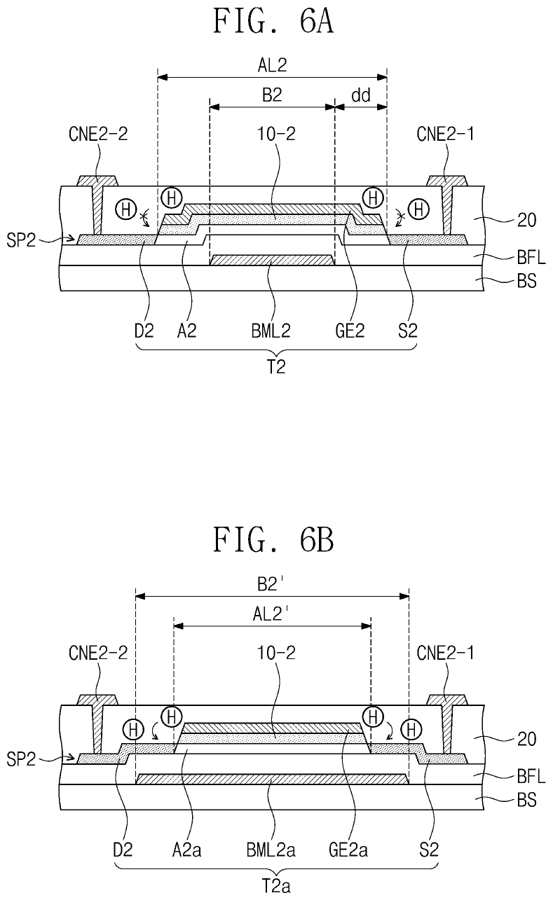

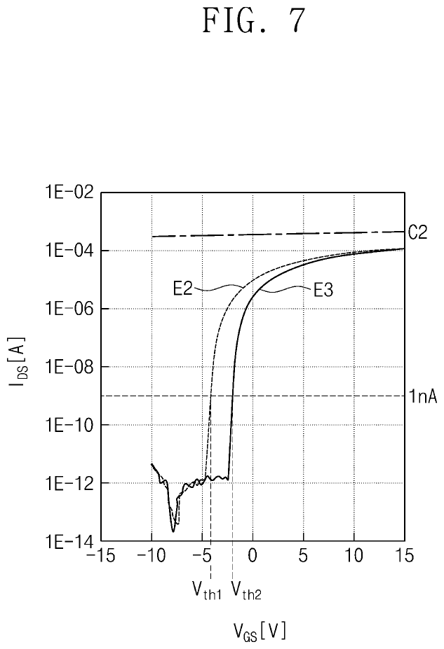

FIG. 6A is a cross-sectional view of a second transistor T2 according to an embodiment of the present disclosure. FIG. 6B is a cross-sectional view of a second transistor T2a according to a comparative example. FIG. 7 is a graph depicting voltage-current characteristics according to the embodiment of the present disclosure and the comparative example. The description given above with reference to FIGS. 3A and 3B may be applied to the second transistor T2 of FIG. 6A.

Referring to FIG. 6A, the length B2 of the second conductive pattern BML2 may be smaller than the length AL2 of the second channel region A2. The outer ends of the second conductive pattern BML2 may overlap the second channel region A2. The second channel region A2 may have steps in regions corresponding to the outer ends of the second conductive pattern BML2 and may be disposed over the second conductive pattern BML2.

The second gate electrode GE2 may be disposed over the second channel region A2 having a stepped shape and may have a shape corresponding to the shape of the second channel region A2. For example, the second gate electrode GE2 may also have the stepped shape and may cover the second channel region A2. The length L2 (refer to FIG. 3B) of the second gate electrode GE2 may be greater than the length B2 of the second conductive pattern BML2.

Referring to FIG. 6B, in the comparative example, the length B2′ of a second conductive pattern BML2a may be greater than the length AL2′ of a second channel region A2a. For example, in a plan view, the second conductive pattern BML2a may overlap the entire second channel region A2a. In a plan view, outer ends of the second conductive pattern BML2a might not overlap the second channel region A2a. In the comparative example, the second channel region A2a may have a substantially flat shape and may be disposed over the second conductive pattern BML2a.

A second gate electrode GE2a may be disposed over the second channel region A2a having a substantially flat shape. Accordingly, the second gate electrode GE2a may also have a substantially flat shape and may cover the second channel region A2a. The length of the second gate electrode GE2a may be smaller than the length B2′ of the second conductive pattern BML2a.

Referring to FIG. 7, current-voltage characteristics of switching transistors of embodiment 2 (E2), embodiment 3 (E3), and comparative example 2 (C2) are illustrated. The switching transistors of embodiment 2 (E2) and embodiment 3 (E3) correspond to the second transistor T2 of FIG. 6A, and the switching transistor of comparative example 2 (C2) corresponds to the second transistor T2a of FIG. 6B. Embodiment 2 (E2) and Embodiment 3 (E3) have the same structure of the second transistor T2. However, embodiment 2 (E2) and Embodiment 3 (E3) differ from each other in terms of the length difference dd (refer to FIG. 6A) between the outer end of the second conductive pattern BML2 and the boundary of the second channel region A2.

Referring to FIGS. 6A, 6B, and 7, as the second channel region A2 of the second transistor T2 has the stepped shape, the actual length of the second channel region A2 may be increased. For example, based on the same area, the actual length of the second channel region A2 having the stepped shape may be greater than the length of the flat second channel region A2a.

To smoothly perform an On/Off function, the length of the second channel region A2 of the second transistor T2 corresponding to a switching transistor may be designed to be short. The effective length of the second channel region A2 may be decreased by hydrogen introduced in a forming process of an insulating layer (e.g., the second insulating layer 20) formed on the second channel region A2. However, since the second channel region A2 has the stepped shape due to the second conductive pattern BML2, a decrease in the effective length of the second channel region A2 may be minimized, and the effective length of the second channel region A2 may be close to the actual length of the second channel region A2.

Furthermore, since the second gate electrode GE2 disposed over the second channel region A2 has the stepped shape corresponding to the second channel region A2, diffusion of hydrogen generated from the second insulating layer 20 into the second channel region A2 may be effectively blocked. Accordingly, the reliability of the switching transistor (or, the second transistor T2) may be increased. For example, as illustrated in FIG. 7, the switching transistors (or, the second transistors T2) of embodiments E2 and E3 may have semiconductor characteristics having an On/Off function.

However, in the switching transistor (or, the second transistor T2a) of comparative example 2 (C2), hydrogen is introduced into the second channel region A2a in a forming process of the second insulating layer 20, and a carrier concentration is increased. Furthermore, the second gate electrode GE2a disposed over the flat second channel region A2a may also be substantially flat, and therefore the second gate electrode GE2a may fail to block the introduction of hydrogen better than the second gate electrode GE2. Due to this, when compared to the actual length of the second channel region A2a, the effective length of the second channel region A2a may be decreased, and the switching transistor may lose semiconductor characteristics and may be short-circuited as illustrated in FIG. 7.

Referring to FIGS. 6A and 7, the magnitude of a threshold voltage of the second transistor T2 may be diversely designed depending on the length difference dd between the outer end of the second conductive pattern BML2 and the boundary of the second channel region A2. Embodiment 2 (E2) corresponds to the case in which the length difference dd is 0.5 μm, and embodiment 3 (E3) corresponds to the case in which the length difference dd is 1.5 μm. As the length difference dd is increased, the magnitude of the threshold voltage may tend to decrease. For example, when voltages at 1 nA drive current IDs are compared, the voltage Vₜₕ₁ in embodiment 2 (E2) may be about −3.96 V, and the voltage Vₜₕ₂ in embodiment 3 (E3) may be about −1.92 V.

The reliability of the second transistor T2 may be increased by adjusting the length B2 of the second conductive pattern BML2, the length AL2 of the second channel region A2, and the length difference dd of the second conductive pattern BML2 and the second channel region A2 according to characteristics required for the second transistor T2.

The transistors, according to the embodiments of the present disclosure, may include metal oxide and thus may have high electron mobility and reduced leakage current.

In the drive transistor, according to the embodiments of the present disclosure, the conductive pattern disposed under the channel region may serve as the gate electrode, and thus the effective length of the channel region may be increased. A field effect may be reduced by an increase in the thickness of the gate insulating film disposed between the gate electrode and the channel region, and thus the drive voltage range may be increased.

In the switching transistor according to the embodiments of the present disclosure, the length of each of the gate electrode and the channel region may be longer than the length of the conductive pattern disposed under the channel region. Accordingly, the channel region may have the stepped shape, and the gate electrode may cover the stepped channel region. Thus, the carrier concentration may be prevented from being increased by infiltration of hydrogen generated from the insulating film into the channel region. As a result, the transistor may be prevented from being short-circuited, and the effective length of the channel region may remain substantially the same as the actual length of the channel region.

While the present disclosure has been described with reference to embodiments thereof, it will be apparent to those of ordinary skill in the art that various changes and modifications may be made thereto without departing from the spirit and scope of the present disclosure.

What is claimed is:

1. A display panel, comprising:
a light emitting element; and
a pixel circuit electrically connected to the light emitting element, the pixel circuit including a first transistor and a second transistor,
wherein the first transistor includes:
a first semiconductor pattern including a first source region, a first drain region, and a first channel region that is disposed between the first source region and the first drain region;
a first gate electrode disposed over the first channel region; and
a first conductive pattern disposed under the first channel region,
wherein the second transistor includes:
a second semiconductor pattern including a second source region, a second drain region, and a second channel region that is disposed between the second source region and the second drain region;
a second gate electrode disposed over the second channel region; and
a second conductive pattern disposed under the second channel region,
wherein the first conductive pattern overlaps the first gate electrode,
wherein a length of the first conductive pattern is longer than a length of the first gate electrode,
wherein the second conductive pattern overlaps the second gate electrode, and
wherein a length of the second conductive pattern is shorter than a length of the second gate electrode.

2. The display panel of claim 1, wherein each of the first semiconductor pattern and the second semiconductor pattern includes a metal oxide semiconductor material.

3. The display panel of claim 1, wherein the first semiconductor pattern and the second semiconductor pattern are disposed on a same layer.

4. The display panel of claim 1, wherein the first conductive pattern and the second conductive pattern include a same material.

5. The display panel of claim 1, wherein the first conductive pattern and the second conductive pattern are disposed on a same layer.

6. The display panel of claim 1, wherein the length of the second conductive pattern is shorter than the length of the first conductive pattern.

7. The display panel of claim 1, wherein the second conductive pattern includes a plurality of patterns overlapping the second channel region and spaced apart from each other.

8. The display panel of claim 1, wherein the second channel region has a stepped shape corresponding to an outer end of the second conductive pattern.

9. The display panel of claim 8, wherein the second gate electrode has a stepped shape corresponding to the stepped shape of the second channel region.

10. The display panel of claim 1, wherein the second conductive pattern is electrically connected to the second gate electrode.

11. The display panel of claim 1, wherein the second conductive pattern is a floating electrode.

12. The display panel of claim 1, wherein the light emitting element includes a first electrode, a second electrode, and an emissive layer that is disposed between the first electrode and the second electrode, and
wherein the first electrode is electrically connected to the first source region.

13. The display panel of claim 12, wherein the first source region is electrically connected to the first gate electrode.

14. The display panel of claim 1, further comprising:
a buffer layer disposed between the first conductive pattern and the first channel region;
a first insulating layer disposed between the first channel region and the first gate electrode; and
a second insulating layer disposed on the first gate electrode,
wherein the buffer layer, the first insulating layer, and/or the second insulating layer includes an inorganic layer.

15. The display panel of claim 14, wherein the buffer layer is thicker than the first insulating layer.

16. The display panel of claim 14, wherein the first insulating layer includes an insulating pattern that overlaps the first channel region without overlapping the first source region or the first drain region.

17. A display panel, comprising:
a light emitting element; and
a pixel circuit electrically connected to the light emitting element, the pixel circuit including a drive transistor and a switching transistor,
wherein the drive transistor includes:
a first semiconductor pattern including a first channel region, a first source region, and a first drain region;
a first gate electrode disposed over the first channel region and electrically connected to the first source region; and
a first conductive pattern disposed under the first channel region, wherein the switching transistor includes:
a second semiconductor pattern including a second channel region, a second source region, and a second drain region;
a second gate electrode disposed over the second channel region; and
a second conductive pattern disposed under the second channel region,
wherein the second conductive pattern overlaps the second gate electrode, and
wherein a length of the second conductive pattern is shorter than a length of the second gate electrode.

18. The display panel of claim 17, wherein in a plan view, an outer end of the first conductive pattern is spaced apart from the first channel region, and an outer end of the second conductive pattern overlaps the second channel region.

19. The display panel of claim 17, wherein each of the second channel region and the second gate electrode has a stepped shape.

20. The display panel of claim 17, wherein the second conductive pattern includes a plurality of patterns spaced apart from each other in a region corresponding to the second channel region.
